(19) United States
(12) Patent Application Publication
(10) Pub. No.: US 2014/0312475 A1
(43) Pub. Date: Oct. 23, 2014

(54) DIE REUSE IN ELECTRICAL CIRCUITS

(71) Applicant: LSI CORPORATION, San Jose, CA (US)

(72) Inventors: Anwar Ali, San Jose, CA (US); Gokulnath S. Sulur, Sunnyvale, CA (US); Tauman T. Lau, San Jose, CA (US)

(73) Assignee: LSI CORPORATION, San Jose, CA (US)

(21) Appl. No.: 13/871,216

(22) Filed: Apr. 26, 2013

Related U.S. Application Data
(60) Provisional application No. 61/813,706, filed on Apr. 19, 2013.

(51) Int. Cl. H01L 23/538

(52) U.S. Cl. CPC H01L 23/5386
USPC 257/666

(57) ABSTRACT

A die having multiple sets of contact pads, with each such set having two or more contact pads distributed over the die and electrically interconnected using a respective electrical intra-die path to enable die reuse in a manner that causes electrical inter-die buses to be relatively short in length. Each electrical intra-die path can optionally include one or more respective buffer circuits configured to reduce degradation of the various signals that are being shared by the reused dies. In some embodiments, multiple reused dies can be arranged in a linear or two-dimensional array on an interposer or on the package substrate and packaged together with one or more non-reused dies in a single integrated-circuit package.

### FIELD

The present disclosure relates to integrated-circuit (IC) packaging and, more specifically but not exclusively, to die reuse in system-in-package assemblies, multi-chip modules, chip-on-board devices, 2.5D integrated circuits, and printed-circuit-board assemblies.

### BACKGROUND

As used herein, the term “die reuse” refers to a circuit design in which two or more identical dies (also sometimes spelled as dice) are placed into one IC package or on one circuit board to cause the resulting circuit to have a higher functional capacity. For example, multiple identical memory dies can be arrayed in one package to increase the memory volume therein. However, one problem with die reuse is that signal lines corresponding to different reused dies need to be appropriately tied together within the package or on the circuit board, e.g., by wrapping the signal lines outside the dies or by using specially designed redistribution layers. Since the continued industry trend is to shrink the package size while trying to pack together progressively more dies, these approaches are becoming relatively difficult to implement without compromising the signal quality and/or bus speeds.

### SUMMARY

Disclosed herein are various embodiments of a die having multiple sets of contact pads, with each such set having two or more contact pads distributed over the die and electrically interconnected using a respective electrical intra-die path to enable die reuse in a manner that causes electrical inter-die buses to be relatively short in length. Each electrical intra-die path can optionally include one or more respective buffer circuits configured to reduce degradation of the various signals that are being shared by the reused dies. In some embodiments, multiple reused dies can be arranged in a linear or two-dimensional array on an interposer or on a package substrate and packaged together with one or more non-reused dies in a single IC package.

### BRIEF DESCRIPTION OF THE FIGURES

Other embodiments of the disclosure will become more fully apparent from the following detailed description and the accompanying drawings, in which:

FIGS. 1A-1B show schematic top and cross-sectional side views, respectively, of a hybrid circuit according to an embodiment of the disclosure;

FIG. 2 shows a schematic cross-sectional side view illustrating some structural details of the hybrid circuit shown in FIGS. 1A-1B according to an embodiment of the disclosure;

FIG. 3 shows a schematic cross-sectional side view illustrating some structural details of the hybrid circuit shown in FIGS. 1A-1B according to an alternative embodiment of the disclosure;

FIG. 4 shows a schematic top view of a die according to an embodiment of the disclosure;

FIG. 5 shows a block diagram of an IC package having a plurality of identical dies similar to the die shown in FIG. 4 according to an embodiment of the disclosure; and

FIG. 6 shows a circuit diagram of a buffer circuit that can be used in the die shown in FIG. 4 according to an embodiment of the disclosure.

### DETAILED DESCRIPTION

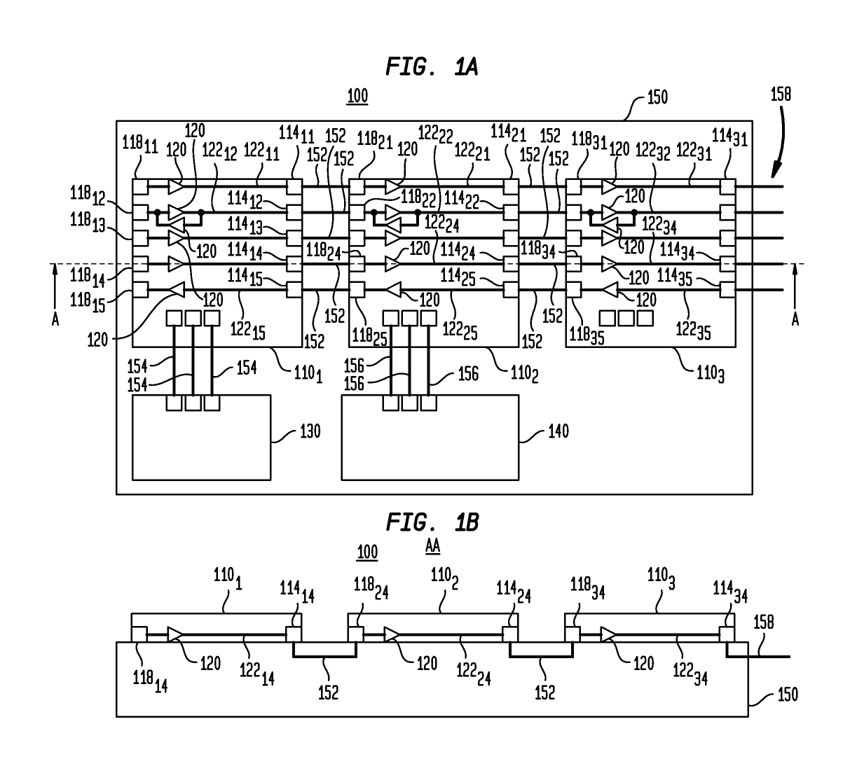

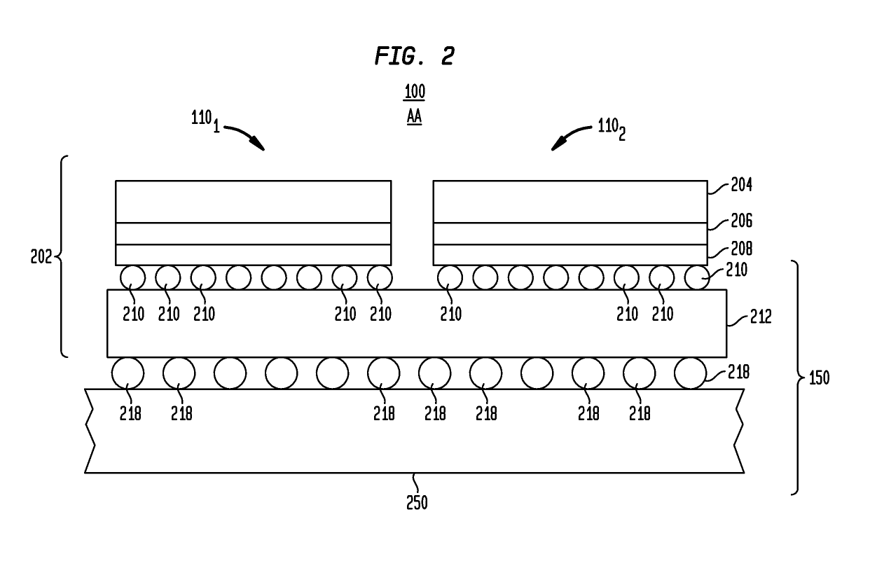

FIGS. 1A-1B show a schematic top view and a schematic cross-sectional side view, respectively, of a hybrid circuit 100 according to an embodiment of the disclosure. As used herein, the term “hybrid circuit” refers to an electrical circuit comprising a set of circuit components mounted on a common base. A representative hybrid circuit may contain one or more packaged or non-packaged integrated circuits and one or more discrete components, such as resistors, capacitors, and inductors, all attached to the common base. Electrical connections between the integrated circuits and discrete components can be formed, e.g., using patterned conducting (such as metal) layers located within the body and/or on the surface of the base. In some embodiments, some discrete components may be fabricated directly on the surface of the base. The base may include any combination of one or more substrates, one or more redistribution layers (RDLs), one or more interposers, one or more laminate plates, and one or more circuit boards. Representative examples of hybrid circuit 100 are, without limitation, a system-in-package (SiP) assembly, a multi-chip module (MCM), a chip-on-board (CoB) device, a 2.5D integrated circuit, and a printed-circuit-board (PCB) assembly.

Circuit 100 comprises dies 110₁-110₃, 130, and 140 attached to a common base 150. As used herein, the term “die” refers to a monolithic block of processed semiconductor material(s), on which a given functional circuit has been fabricated. The die labeling used in FIGS. 1A-1B implies that circuit 100 has three different types of dies. More specifically, dies 110₁-110₃ are identical dies of the same (e.g., first) type; die 130 is a die of a second type; and die 140 is a die of a third type. For example, in one embodiment, each of dies 110₁-110₃ can contain a memory circuit; die 130 can contain a digital logic circuit; and die 140 can contain an analog RF circuit. Other die-type combinations and/or numbers of dies per hybrid circuit are also contemplated.

As used herein, the term “identical dies” refers to a set of two or more dies that are physical copies of each other and of a master copy. These physical copies are “identical” to one another within the corresponding manufacturing tolerances and semiconductor-process variances. Typically, such “identical dies” are produced in relatively large batches using wafers of electronic-grade silicon or other suitable semiconductor material(s) through a multi-step sequence of photolithographic and chemical processing steps, during which electronic circuits are gradually created on the wafer. Each wafer is then cut (“diced”) into many pieces (dies), each containing a respective copy of the functional circuit that is being fabricated. If the circuit is programmable, then it is possible that different copies of the circuit are programmed differently in the end product. However, as used herein, the term “identical dies” should be construed to cover such differently programmed copies of the same circuit. If the same set of photolithographic masks and the same sequence of chemical processing steps are used in different production batches, then some “identical dies” used in the final product can conceivably come from such different production batches.

Base 150 comprises a signal-routing structure, only a portion of which is shown in FIGS. 1A-1B. As indicated in FIGS. 1A-1B, the signal-routing structure in base 150 comprises: (i) a plurality of electrical inter-die paths or buses 152 configured to electrically connect dies 110₁-110₃; (ii) a plurality of electrical inter-die paths or buses 154 configured to electrically connect dies 110₁ and 130; (iii) a plurality of electrical inter-die paths or buses 156 configured to electrically connect dies 110₂ and 140; and (iv) an input/output (I/O) interface 158 configured to electrically connect circuit 100 and one or more external circuits (not explicitly shown in FIGS. 1A-1B).

In various embodiments, each of dies 110₁-110₃ can be a memory circuit, a custom ASIC, a standard electronic product, etc. For illustration purposes and without any implied limitation, the subsequent description of circuit 100 is given in reference to an embodiment in which each of dies 110₁-110₃ contains a memory circuit. One of ordinary skill in the art will understand how to make and use other embodiments of circuit 100, in which dies 110 contain other circuit types.

In one embodiment, each of dies 110₁-110₃ includes a respective plurality of memory cells of a random-access memory (RAM, not explicitly shown in FIGS. 1A-1B) and a respective plurality of input/output contact pads 114 and 118 electrically connected to the memory cells. In various alternative embodiments, a contact pad 114 can be configured to operate as an input pad, an output pad, or a bidirectional input/output pad. Similarly, a contact pad 118 can be configured to operate as an input pad, an output pad, or a bidirectional input/output pad.

Each contact pad 114 is electrically connected to at least one contact pad 118 via a respective electrical intra-die path 122, e.g., as indicated in FIG. 1B. Contact pads 114 and 118 corresponding to different dies 110₁-110₃ are further electrically connected to one another using electrical paths 152 in a manner that enables dies 110₁-110₃ to have a fully shared access to I/O interface 158, e.g., as indicated in FIGS. 1A-1B.

In one embodiment, an electrical path 122 in die 110_{;} (where i=1, 2, 3) may optionally include one or more respective buffer circuits 120. For example, an electrical path 122ᵢ₁ that electrically connects contact pads 114ᵢ₁ and 118ᵢ₁ in die 110ᵢ has a buffer circuit 120 configured such that (i) the signal applied to contact pad 118ᵢ₁, serves as a “non-buffered” input to that buffer circuit and (ii) the signal that appears at contact pad 114ᵢ₁ is a “buffered” output generated by that buffer circuit based on the “non-buffered” input. Thus, for electrical path 122ᵢ₁, contact pad 118ᵢ₁ is configured to operate as an input pad while contact pad 114ᵢ₁ is configured to operate as an output pad. In another example, an electrical path 122ᵢ₅ that electrically connects contact pads 114ᵢ₅ and 118ᵢ₅ in die 110ᵢ has a buffer circuit 120 configured such that (i) the signal applied to contact pad 114ᵢ₅, serves as a “non-buffered” input to that buffer circuit and (ii) the signal that appears at contact pad 118ᵢ₅ is a “buffered” output generated by that buffer circuit based on the “non-buffered” input. Thus, for electrical path 122ᵢ₅, contact pad 114ᵢ₅ is configured to operate as an input pad while contact pad 118ᵢ₅ is configured to operate as an output pad. In yet another example, an electrical path 122ᵢ₂ that electrically connects contact pads 114ᵢ₂ and 118ᵢ₂ in die 110ᵢ has two buffer circuits 120 configured as indicated in FIG. 1A. Thus, for electrical path 122ᵢ₂, each of contact pads 114ᵢ₂ and 118ᵢ₂ can operate both as an input pad and as an output pad, for bidirectional signal routing.

As used herein, the term “buffer circuit” refers to an electronic amplifier that is designed to have an amplifier gain of substantially one. Buffer circuits are often used for impedance matching and/or to optimize (e.g., maximize) energy transfer between different circuits or between different portions of the same circuit. A buffer circuit is also sometimes referred to in the relevant literature as a voltage follower. Suitable buffer circuits that can be used to implement buffer circuits 120 in die 110 are disclosed, e.g., in U.S. Pat. Nos. 4,725,746 and 5,229,659, both of which are incorporated herein by reference in their entirety.

In one embodiment, contact pads in one set of electrically connected pad pairs 114ᵢⱼ and 118ᵢⱼ in die 110ᵢ (where i=1, 2, 3 and j=1, 2, . . . , 5) are connected to bit lines (not explicitly shown in FIGS. 1A-1B) of the RAM, and contact pads in another set of electrically connected pad pairs 114ᵢⱼ and 118ᵢⱼ in die 110ᵢ are connected to word lines (also not explicitly shown in FIGS. 1A-1B) of the RAM. Still other sets of pad pairs 114ᵢⱼ/118ᵢⱼ in die 110ᵢ can be connected, e.g., to refresh counters, sense amplifiers, write-enable lines, and other circuitry that enables conventional memory operations.

To access a memory cell in one of dies 110₁-110₃, an external memory controller (not explicitly shown in FIGS. 1A-1B) applies an address-select signal to an appropriate subset of signal lines in I/O interface 158. Circuit 100 can then deliver the address-select signal to each of dies 110₁-110₃ using the appropriate subset of electrical paths 152 and 122.

For example, circuit 100 can route an address-select signal as follows. I/O interface 158 applies the address-select signal to die 110₃, e.g., via contact pad 114₃₅. Electrical path 122₃₅ transfers the address-select signal from contact pad 114₃₅, via the respective buffer circuit 120, to contact pad 118₃₅. The electrical path 152 connected to contact pad 118₃₅ then applies the address-select signal to die 110₂ via contact pad 114₂₅. Electrical path 122₂₅ transfers the address-select signal from contact pad 114₂₅, via the respective buffer circuit 120, to contact pad 118₂₅. The electrical path 152 connected to contact pad 118₂₅ then applies the address-select signal to die 110₁ via contact pad 114₁₅. Note that contact pad 118₁₅ is non-functional in this particular memory-access operation and can in principle be absent in die 110₁, but is nevertheless present therein solely due to the die reuse in circuit 100.

In one embodiment, the address-select signal contains, e.g., a die-select portion, a bit-line-select portion, and a word-line-select portion, which unambiguously identify the memory cell that is being accessed. Each of dies 110₁-110₃ can be appropriately programmed in a manner that enables the die-select portion of the address-select signal to select the intended one of the dies. Suitable programmable circuitry that can be incorporated into die 110 for this purpose is disclosed, e.g., in U.S. Patent Application Publication No. 2008/0220565, which is incorporated herein by reference in its entirety. After the intended one of dies 110₁-110₃ is selected using the die-select portion of the address-select signal, the bit-line-select portion and the word-line-select portion of the address-select signal can be used in a conventional manner to select the intended memory cell within the selected die.

To read out a bit value stored in a memory cell located, e.g., in die 110₁, the external memory controller first selects that memory cell, e.g., as described above, using an appropriate address-select signal. A corresponding sense amplifier in die 110₁ then senses the bit value stored in the selected memory cell and applies the sensed signal, e.g., to contact pad 114₁₄. The electrical path 152 connected to contact pad 114₁₄ then applies the sensed signal to contact pad 118₂₄ in die 110₂. Electrical path 122₂₄ in die 110₂ then transfers the sensed signal from contact pad 118₂₄, via the respective buffer circuit 120, to contact pad 114₂₄. The electrical path 152 connected to contact pad 114₂₄ then applies the sensed signal to contact pad 118₃₄ in die 110₃. Electrical path 122₃₄ in die 110₃ then transfers the sensed signal from contact pad 118₃₄, via the respective buffer circuit 120, to contact pad 114₃₄. Finally, contact pad 114₃₄ applies the sensed signal to the corresponding signal line in I/O interface 158 (see, e.g., FIG. 1B).

One benefit of having electrical paths 122ᵢᵢ and the corresponding pad pairs 114018ᵢⱼ in dies 110ᵢ is that they enable base 150 to have relatively short electrical paths 152 between the dies. In general, conducting tracks that are used to implement electrical paths 152 in base 150 are significantly (e.g., orders of magnitude) larger than the conducting tracks that are used to implement electrical paths 122 in dies 110. This size difference impacts, e.g., the circuit performance and power consumption, with a circuit embodiment having shorter conducting tracks in base 150 generally exhibiting better circuit-performance and power-consumption characteristics. In addition, buffers 120 ensure that the quality of transported signals is relatively high, e.g., by reducing signal distortions imposed by circuit 100.

Another benefit of having electrical paths 122ᵢⱼ and the corresponding pad pairs 114ᵢⱼ/118ᵢⱼ in dies 110ᵢ is that they can be used to ease routing congestion in base 150. As a result, base 150 in circuit 100 can support a relatively large number of die-to-die connections, which enables the circuit to potentially have a relatively large number of dies 110, thereby providing a correspondingly high memory volume for the circuit.

FIG. 2 shows a schematic cross-sectional side view illustrating some structural details of hybrid circuit 100 (FIGS. 1A-1B) according to an embodiment of the disclosure. More specifically, FIG. 2 shows a portion of circuit 100 corresponding to dies 110₁ and 110₂. In this particular embodiment, dies 110₁-110₃, 130, and 140 are all parts of a single IC package 202. IC package 202 further comprises a package substrate 212, to which dies 110₁ and 110₂ are attached using flip-chip solder bumps 210. IC package 202 is in turn attached to a printed circuit board 250 using package solder bumps 218. In the nomenclature used above in the description of FIGS. 1A-1B, solder bumps 210, substrate 212, solder bumps 218, and printed circuit board 250 are all parts of base 150. Each electrical path 152 (see FIGS. 1A-1B) normally has a portion thereof located in substrate 212. In some embodiments, at least one of electrical paths 152 may also have one or more respective portions thereof located in printed circuit board 250.

In one embodiment, a die 110 in IC package 202 comprises a die substrate 204, a semiconductor-device layer 206, and a metal-interconnect structure 208. Device layer 206 and metal-interconnect structure 208 are fabricated, in a conventional manner, on a surface of die substrate 204. Contact pads 114 and 118 (not explicitly shown in FIG. 2, see FIGS. 1A-1B) are typically part of or electrically connected to metal-interconnect structure 208. After all layers of die 110 have been fabricated, the die is (i) flipped over so that metal-interconnect structure 208 faces package substrate 212 and (ii) attached to the package substrate using flip-chip solder bumps 210. Package substrate 212 can be, e.g., of a laminate variety and include several tracking layers having metal tracks in them and metal vias configured to electrically connect different tracking layers to one another. Package substrate 212, with the various dies attached to it, is packaged in a conventional manner, with the resulting packaged integrated circuit being IC package 202. One of ordinary skill in the art will understand that, in addition to IC package 202, printed circuit board 250 can host other IC packages and/or discrete components (not explicitly shown in FIG. 2) attached to the board in a similar manner.

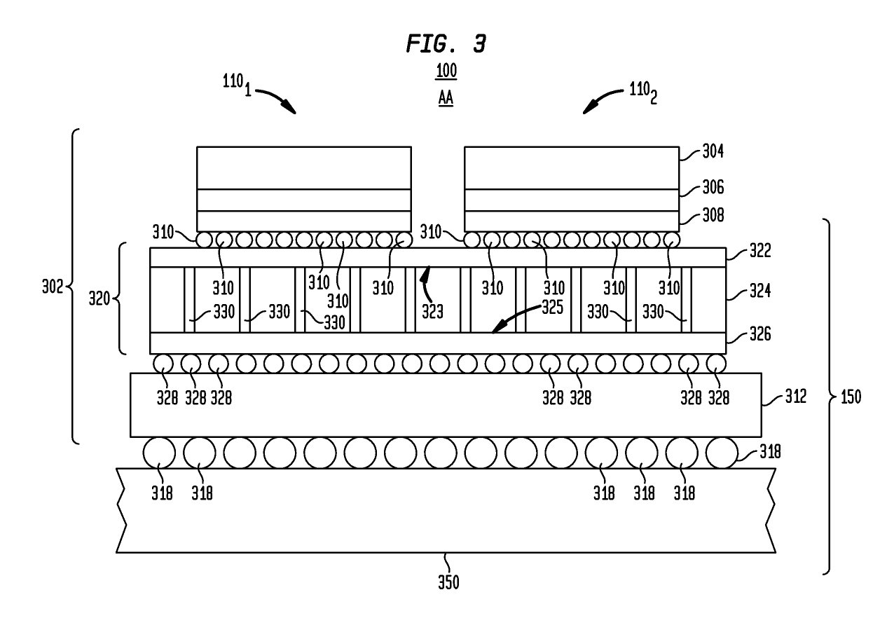

FIG. 3 shows a schematic cross-sectional side view illustrating some structural details of hybrid circuit 100 (FIGS. 1A-1B) according to an alternative embodiment of the disclosure. More specifically, FIG. 3 shows a portion of circuit 100 corresponding to dies 110₁ and 110₂. In this particular embodiment, dies 110₁-110₃, 130, and 140 are all parts of a single IC package 302. IC package 302 further comprises an interposer 320, to which dies 110₁ and 110₂ are attached using micro solder bumps 310. Interposer 320 is in turn attached to a package substrate 312 using solder bumps 328. IC package 302 is attached to a printed circuit board 350 using package solder bumps 318. In the nomenclature used above in the description of FIGS. 1A-1B, solder bumps 310, interposer 320, solder bumps 328, substrate 312, solder bumps 318, and printed circuit board 350 are all parts of base 150. Each electrical path 152 (see FIGS. 1A-1B) normally has a portion thereof located in interposer 320. In some embodiments, at least some of electrical paths 152 may further have one or more respective portions thereof located in package substrate 312 and possibly in printed circuit board 350.

The two embodiments of circuit 100 shown in FIGS. 2 and 3, respectively, have many analogous elements that are designated in these two figures using numerical labels having the same last two digits, and with the first digit of the corresponding label being “two” in FIG. 2 and “three” in FIG. 3. For a description of the elements shown in FIG. 3 that have analogous counterparts in FIG. 2, the reader is directed to the above-presented description of FIG. 2. The focus of the description of FIG. 3 below is primarily on various differences between these two embodiments of circuit 100.

One significant difference between the two embodiments of circuit 100 shown in FIGS. 2 and 3 is that the embodiment shown in FIG. 3 has interposer 320. Hybrid circuits having an interposer functionally similar to interposer 320 are sometimes referred to in the relevant literature as 2.5D (or two-and-a-half dimensional) circuits.

In one embodiment, interposer 320 comprises a silicon substrate 324 having a first surface 323 and an opposing second surface 325. Interposer 320 further comprises (i) a first signal-routing structure 322 formed adjacent to surface 323 of silicon substrate 324 and (ii) a second signal-routing structure 326 formed adjacent to surface 325 of the silicon substrate. Various conducting paths in routing structure 322 are electrically connected to appropriate conducting paths in routing structure 326 using a plurality of through-hole conductors 330, each occupying a respective hole formed in silicon substrate 324.

Functionally, interposer 320 serves as a signal-routing device configured to mutually connect dies 110₁-110₃, 130, and 140 and package substrate 312. In one embodiment, contact pads in the dies of IC package 302 (such as contact pads 114 and 118 in dies 110₁-110₃, see FIGS. 1A-1B) have a relatively fine pitch of, e.g., about 10 μm. In contrast, contact pads located at the inner package surface of package substrate 312 have a coarser pitch of, e.g., about 100 μm. Thus, interposer 320 also serves as an adaptor between the on-die pitch and the inner package-substrate pitch. Since contact pads located on the surface of printed circuit board 350 typically have a pitch that is even coarser than 100 μm, package substrate 312 may itself serve as an adaptor between the inner package-substrate pitch and the on-board pitch. Suitable interposers that can be used as interposer 320 in IC package 302 are disclosed, e.g., in U.S. Pat. Nos. 8,149,585, 8,026,610, and 7,901,986, all of which are incorporated herein by reference in their entirety.

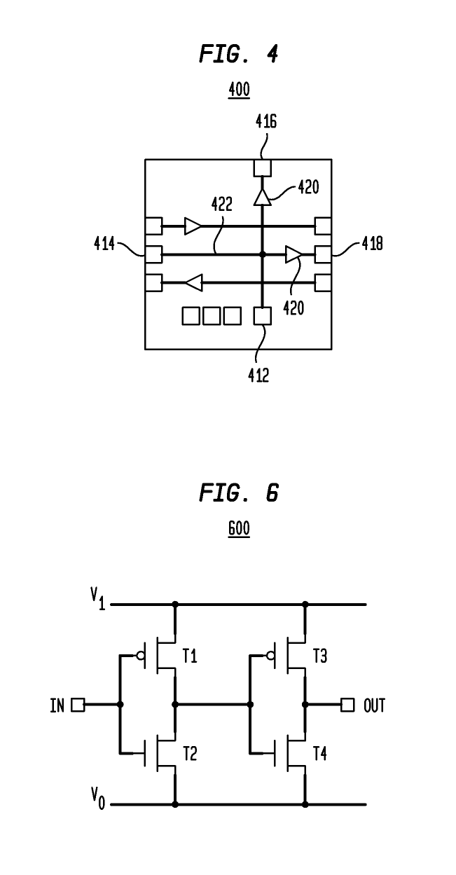

FIG. 4 shows a schematic top view of a die 400 according to an alternative embodiment of the disclosure. Die 400 is generally analogous to die 110 (see FIGS. 1A-1B). For example, recall that die 110ᵢ has a plurality of contact-pad pairs 114ᵢⱼ/118ᵢⱼ (where j=1, 2, . . . , 5), with each contact-pad pair being electrically connected through electrical intra-die path 122ᵢⱼ, which causes each pad in the pair to carry a respective copy of the same signal. Similarly, die 400 has a plurality of contact-pad sets, with the contact pads in each set being electrically interconnected through a respective electrical intra-die path, which causes each contact pad in the set to carry a respective copy of the same signal. However, one difference between dies 110 and 400 is that at least some contact-pad sets in die 400 have more than two contact pads per set.

For example, as indicated in FIG. 4, die 400 has a contact-pad set consisting of contact pads 412, 414, 416, and 418. These contact pads are electrically interconnected through an electrical intra-die path 422 having two buffer circuits 420 therein. This electrical interconnection causes each of contact pads 412, 414, 416, and 418 to carry a respective copy of the same signal, either generated internally by die 400 or applied to die 400 by an external circuit. Contact pads 412, 414, 416, and 418 are illustratively shown in FIG. 4 as each being located in close proximity to a respective one of the four edges of die 400. In various alternative embodiments, a different contact-pad placement is also possible. Due to the shown configuration of buffer circuits 420 in electrical intra-die path 422, each of contact pads 412 and 414 is configured to operate as an input pad, and each of contact pads 416 and 418 is configured to operate as an output pad. More specifically, in operation, a signal applied to one of contact pads 412 and 414 is repeated by the two buffer circuits 420 in electrical path 422 and appears as a respective buffered copy of that signal at each of contact pads 416 and 418.

In various alternative embodiments, die 400 can be designed to have electrical intra-die paths with configurations of buffer circuits that may be different from the configuration of buffer circuits 420 in electrical intra-die path 422. Electrical intra-die paths corresponding to different contact-pad sets can be adapted for unidirectional or bidirectional signal routing. Different contact-pad sets may have different respective numbers of contact pads per set. Advantageously, multiple contact pads belonging to the same contact-pad set can be used to design an electrical die-to-die interconnect that is optimal for the corresponding hybrid circuit, e.g., in terms of having relatively short inter-die buses (such as paths 152, FIGS. 1A-1B) and/or decreasing the density of signal-routing tracks at certain locations within the corresponding circuit base (such as base 150, FIGS. 1A-1B).

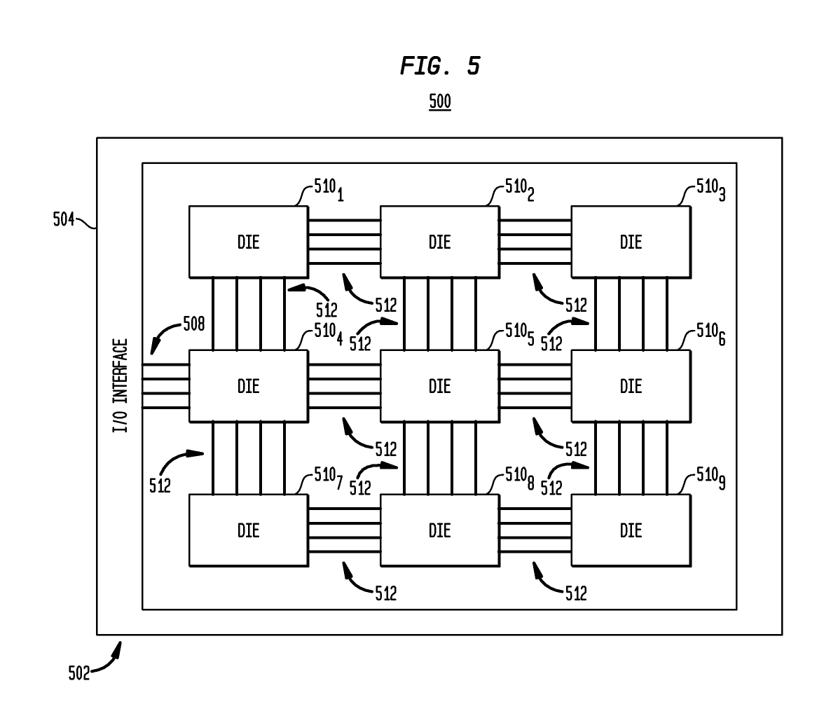

FIG. 5 shows a block diagram of an IC package 500 according to an embodiment of the disclosure. IC package 500 is designed using the concept of die reuse and includes a plurality of identical dies 510. In various embodiments, IC package 500 can be used in a hybrid circuit analogous to hybrid circuit 100 in a manner similar to that of IC package 202 (FIG. 2) or IC package 302 (FIG. 3).

In one embodiment, a die 510 in IC package 500 has multiple sets of contact pads (not explicitly shown in FIG. 5), with the contact pads in each set being electrically interconnected using a respective electrical intra-die path. At least some of the contact-pad sets in die 510 have four contact pads per set, e.g., arranged similar to contact pads 412, 414, 416, and 418 in die 400 (FIG. 4). This contact-pad arrangement enables dies 510 to be disposed in IC package 500 in a two-dimensional die array 502, e.g., as shown in FIG. 5.

Two-dimensional die array 502 differs from a three-dimensional die stack (such as the die stack disclosed in the above-cited U.S. Patent Application Publication No. 2008/0220565) in that dies 510 in die array 502 are arranged in a single layer on a surface of an interposer (such as interposer 320, FIG. 3) or on a surface of a package substrate (such as package substrate 212, FIG. 2). The term “single layer” implies that each of dies 510 is supported at the same (within manufacturing tolerances) offset distance from the surface to which the dies are attached in IC package 500 using solder bumps, e.g., as indicated in FIGS. 2 and 3 for dies 110. Two-dimensional die array 502 also differs from a linear array, such as the linear array in which dies 110₁-110₃ are arranged in circuit 100 (see, e.g., FIG. 1A). More specifically, a linear die array is characterized in that a single straight line can be drawn through the array such that said straight line passes through each die in the array. In contrast, no such line can be drawn through a two-dimensional array, such as die array 502 in IC package 500.

IC package 500 has an I/O interface 504 configured to provide electrical connections between (i) the various components of the IC package at one side of the interface and (ii) external circuits (not explicitly shown in FIG. 5) at the other side of the interface. Although I/O interface 504 is schematically shown in FIG. 5 as encircling the edges (or lateral periphery) of IC package 500, various embodiments of IC package 500 are not so limited. For example, in various alternative embodiments, electrical contacts, pads, or pins in I/O interface 504 can be arranged in (i) a dual in-line package (DIP) arrangement, (ii) a pin grid array (PGA), (iii) a surface mount array, (iv) a land grid array (LGA), (v) a ball grid array (BGA), or any other suitable spatial arrangement.

Only one of dies 510 (i.e., die 510₄) in IC package 500 is directly electrically connected to I/O interface 504 through a bus 508. The remaining dies 510 (i.e., dies 510₁-510₃ and 510₅-510₉) in IC package 500 are electrically connected to I/O interface 504 only indirectly, through die 510₄ and bus 508. More specifically, each of dies 510₁-510₃ and 510₅-510₉ is configured to have access to I/O interface 504 through an electrical path comprising (i) one or more inter-die busses 512, (ii) one or more electrical intra-die paths that can be analogous to electrical intra-die path 422 (FIG. 4), and (iii) bus 508. Various signals can be routed through IC package 500 to/from individual dies 510, e.g., in a manner similar to that described above in reference to dies 110₁-110₃ of circuit 100 (FIGS. 1A-1B).

FIG. 6 shows a circuit diagram of a buffer circuit 600 that can be used to implement buffer circuit 120 (FIGS. 1A-1B) or buffer circuit 420 (FIG. 4) according to an embodiment of the disclosure. For example, in one embodiment, input terminal IN and output terminal OUT of buffer circuit 600 can be directly electrically connected to contact pads 114₃ and 118₃, respectively, in die 110ᵢ (see FIGS. 1A-1B). Buffer circuit 600 is illustratively shown as a CMOS circuit, although other semiconductor technologies can also be used.

Buffer circuit 600 comprises four MOSFET devices T1-T4 connected, as indicated in FIG. 6, between power supply lines V₀ and V₁. MOSFET devices T1 and T2 are serially connected in a common-gate configuration to form a first inverter. MOSFET devices T3 and T4 are similarly serially connected in a common-gate configuration to form a second inverter. The first inverter is gated by the signal applied to input terminal IN. The second inverter is gated by the signal generated by the channels of MOSFET devices T1 and T2. The signal generated by the channels of MOSFET devices T3 and T4 is applied to output terminal OUT. Due to the two consecutive logic-signal inversions performed by the two inverters in buffer circuit 600, the signal generated at output terminal OUT is a logic copy of the signal applied to input terminal IN.

In one embodiment, terminals IN and OUT of buffer circuit 600 are parts of or electrically connected to the metal-interconnect structure of the corresponding die, such as metal-interconnect structure 208 of die 110 (see FIG. 2). MOSFET devices T1-T4 can be fabricated in a conventional manner in the semiconductor-device layer of the corresponding die, such as semiconductor-device layer 206 of die 110 (see FIG. 2).

According to an embodiment disclosed above in reference to FIGS. 1-6, provided is a circuit comprising: a base (e.g., 150); and a plurality of “identical” dies (e.g., 110, 510) attached to the base, with the term “identical” being used here in the sense explained above in reference to FIGS. 1A-1B and dies 110₁-110₃ shown therein. Each of the identical dies comprises a respective first set of contact pads (e.g., 412-418) and a respective first electrical intra-die path (e.g., 422) configured to interconnect contact pads in the respective first set to cause each contact pad therein to carry a respective copy of a first signal. The base comprises one or more electrical inter-die paths (e.g., 152), each configured to electrically connect a contact pad of the first set of contact pads in one of the identical dies and a contact pad of the first set of contact pads in another one of the identical dies to cause both of said electrically connected contact pads to carry a respective copy of the first signal. In various alternative embodiments, the circuit can be a system-in-package assembly, a multi-chip module, a chip-on-board device, a 2.5D integrated circuit, or a printed-circuit-board assembly.

In some embodiments of the above circuit, the first electrical intra-die path comprises a buffer circuit (e.g., 420, 600).

In some embodiments of any of the above circuits, the first electrical intra-die path is configured for unidirectional signal routing between the contact pads of the first set.

In some embodiments of any of the above circuits, the first electrical intra-die path comprises two or more buffer circuits (e.g., 120) and is configured for bidirectional signal routing between the contact pads of the first set.

In some embodiments of any of the above circuits, one of the identical dies is configured to generate the first signal.

In some embodiments of any of the above circuits, the circuit further comprises an input/output interface configured to: receive the first signal from an external source; and apply a copy of the first signal to a contact pad of the first set of contact pads in one of the identical dies.

In some embodiments of any of the above circuits, the input/output interface is directly electrically connected to exactly one contact pad of the first set of contact pads in exactly one of the identical dies.

In some embodiments of any of the above circuits, the first set of contact pads comprises three or more contact pads.

In some embodiments of any of the above circuits, the base comprises a package substrate (e.g., 212); the plurality of identical dies are attached to the package substrate and packaged to form an integrated-circuit package (e.g., 202); and at least one of the one or more electrical inter-die paths has a path portion located at the package substrate.

In some embodiments of any of the above circuits, the base further comprises an interposer (e.g., 320) located between the plurality of identical dies and the package substrate; and at least one of the one or more electrical inter-die paths has a path portion located at the interposer.

In some embodiments of any of the above circuits, the base further comprises a circuit board (e.g., 250); and the integrated-circuit package is attached to the circuit board together with one or more other integrated-circuit packages.

In some embodiments of any of the above circuits, the integrated-circuit package includes one or more non-identical dies (e.g., 130 and 140) attached to the package substrate.

In some embodiments of any of the above circuits, the plurality of identical dies are arranged in a two-dimensional array (e.g., 502) on a surface of the base.

In some embodiments of any of the above circuits, each of the identical dies comprises a respective second set of contact pads and a respective second electrical intra-die path configured to interconnect contact pads in the respective second set to cause each contact pad therein to carry a respective copy of a second signal different from the first signal; and the base further comprises one or more additional electrical inter-die paths, each configured to electrically connect a contact pad of the second set of contact pads in one of the identical dies and a contact pad of the second set of contact pads in another one of the identical dies to cause both of said electrically connected contact pads to carry a respective copy of the second signal.

In some embodiments of any of the above circuits, each of the identical dies comprises a respective array of memory cells; and each of the identical dies has been programmed to assign different respective addresses to identical memory cells in different identical dies.

In some embodiments of any of the above circuits, the circuit further comprises an input/output interface configured to receive the first signal from a memory controller, wherein the first signal is an address-select signal.

According to an alternative embodiment disclosed above in reference to FIGS. 1-6, provided is an integrated circuit comprising: a die substrate (e.g., 204); a semiconductor-device layer (e.g., 206) attached to the die substrate; a metal-interconnect structure (e.g., 208) attached to the semiconductor-device layer; a first set of contact pads (e.g., 412-418) electrically connected to the metal-interconnect structure; and a first electrical path (e.g., 422) configured to interconnect contact pads in the first set to cause each contact pad therein to carry a respective copy of a first signal, wherein the first electrical path comprises at least one semiconductor device (e.g., T1-T4) located in the semiconductor-device layer.

In some embodiments of the above integrated circuit, the integrated circuit further comprises: a second set of contact pads electrically connected to the metal-interconnect structure; and a second electrical path configured to interconnect contact pads in the second set to cause each contact pad therein to carry a respective copy of a second signal different from the first signal, wherein the second electrical path comprises at least one semiconductor device located in the semiconductor-device layer.

In some embodiments of any of the above integrated circuits, a semiconductor device located in the semiconductor-device layer is configured to generate the first signal.

In some embodiments of any of the above integrated circuits, a contact pad of the first set of contact pads is configured to receive the first signal from an external source.

While this invention has been described with reference to illustrative embodiments, this description is not intended to be construed in a limiting sense. Various modifications of the described embodiments, as well as other embodiments, which are apparent to persons skilled in the art to which the invention pertains are deemed to lie within the scope of the invention as expressed in the following claims.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of various embodiments may be made by those skilled in the art without departing from the scope of the invention as expressed in the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments.

Throughout the detailed description, the drawings, which are not to scale, are illustrative only and are used in order to explain, rather than limit the invention. The use of terms such as height, length, width, top, bottom, is strictly to facilitate the description of the invention and is not intended to limit the invention to a specific orientation. For example, height does not imply only a vertical rise limitation, but is used to identify one of the three dimensions of a three-dimensional structure as shown in the figures. Similarly, while various figures show the different layers as horizontal layers, such orientation is for descriptive purpose only and not to be construed as a limitation.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

It should be appreciated by those of ordinary skill in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Although embodiments of the invention have been described herein with reference to the accompanying drawings, it is to be understood that embodiments of the invention are not limited to the described embodiments, and one of ordinary skill in the art will be able to contemplate various other embodiments of the invention within the scope of the following claims.

What is claimed is:

1. A circuit comprising:
a base (e.g., 150); and
a plurality of identical dies (e.g., 110, 510) attached to the base, wherein:
each of the identical dies comprises a respective first set of contact pads (e.g., 412-418) and a respective first electrical intra-die path (e.g., 422) configured to interconnect contact pads in the respective first set to cause each contact pad therein to carry a respective copy of a first signal; and
the base comprises one or more electrical inter-die paths (e.g., 152), each configured to electrically connect a contact pad of the first set of contact pads in one of the identical dies and a contact pad of the first set of contact pads in another one of the identical dies to cause both of said electrically connected contact pads to carry a respective copy of the first signal.

2. The circuit of claim 1, wherein the first electrical intra-die path comprises a buffer circuit (e.g., 420, 600).

3. The circuit of claim 2, wherein the first electrical intra-die path is configured for unidirectional signal routing between the contact pads of the first set.

4. The circuit of claim 1, wherein the first electrical intra-die path comprises two or more buffer circuits (e.g., 120) and is configured for bidirectional signal routing between the contact pads of the first set.

5. The circuit of claim 1, wherein one of the identical dies is configured to generate the first signal.

6. The circuit of claim 1, further comprising an input/output interface configured to:
receive the first signal from an external source; and
apply a copy of the first signal to a contact pad of the first set of contact pads in one of the identical dies.

7. The circuit of claim 6, wherein the input/output interface is directly electrically connected to exactly one contact pad of the first set of contact pads in exactly one of the identical dies.

8. The circuit of claim 1, wherein the first set of contact pads comprises three or more contact pads.

9. The circuit of claim 1, wherein:
the base comprises a package substrate (e.g., 212);
the plurality of identical dies are attached to the package substrate and packaged to form an integrated-circuit package (e.g., 202); and
at least one of the one or more electrical inter-die paths has a path portion located at the package substrate.

10. The circuit of claim 9, wherein:
the base further comprises an interposer (e.g., 320) located between the plurality of identical dies and the package substrate; and
at least one of the one or more electrical inter-die paths has a path portion located at the interposer.

11. The circuit of claim 9, wherein:
the base further comprises a circuit board (e.g., 250); and
the integrated-circuit package is attached to the circuit board together with one or more other integrated-circuit packages.

12. The circuit of claim 9, wherein the integrated-circuit package includes one or more non-identical dies (e.g., 130 and 140) attached to the package substrate.

13. The circuit of claim 1, wherein the plurality of identical dies are arranged in a two-dimensional array (e.g., 502) on a surface of the base.

14. The circuit of claim 1, wherein:
each of the identical dies comprises a respective second set of contact pads and a respective second electrical intra-die path configured to interconnect contact pads in the respective second set to cause each contact pad therein to carry a respective copy of a second signal different from the first signal; and
the base further comprises one or more additional electrical inter-die paths, each configured to electrically connect a contact pad of the second set of contact pads in one of the identical dies and a contact pad of the second set of contact pads in another one of the identical dies to cause both of said electrically connected contact pads to carry a respective copy of the second signal.

15. The circuit of claim 1, wherein:
each of the identical dies comprises a respective array of memory cells; and
each of the identical dies has been programmed to assign different respective addresses to identical memory cells in different identical dies.

16. The circuit of claim 15, further comprising an input/output interface configured to receive the first signal from a memory controller, wherein the first signal is an address-select signal.

17. An integrated circuit comprising:
a die substrate (e.g., 204);
a semiconductor-device layer (e.g., 206) attached to the die substrate;
a metal-interconnect structure (e.g., 208) attached to the semiconductor-device layer;
a first set of contact pads (e.g., 412-418) electrically connected to the metal-interconnect structure; and
a first electrical path (e.g., 422) configured to interconnect contact pads in the first set to cause each contact pad therein to carry a respective copy of a first signal, wherein the first electrical path comprises at least one semiconductor device (e.g., T1-T4) located in the semiconductor-device layer.

18. The integrated circuit of claim 17, further comprising:
a second set of contact pads electrically connected to the metal-interconnect structure; and
a second electrical path configured to interconnect contact pads in the second set to cause each contact pad therein to carry a respective copy of a second signal different from the first signal, wherein the second electrical path comprises at least one semiconductor device located in the semiconductor-device layer.

19. The integrated circuit of claim 17, wherein a semiconductor device located in the semiconductor-device layer is configured to generate the first signal.

20. The integrated circuit of claim 17, wherein a contact pad of the first set of contact pads is configured to receive the first signal from an external source.
